(19) United States
(12) Patent Application Publication
(10) Pub. No.: US 2017/0076798 A1
(43) Pub. Date: Mar. 16, 2017

(54) LOW OVERHEAD METHOD OF CONTENT ADDRESSABLE MEMORY (CAM) READING

(71) Applicant: QUALCOMM Incorporated, San Diego, CA (US)

(72) Inventors: Joshua Lance PUCKETT, Cary, NC (US); Jason Philip MARTZLOFF, Chapel Hill, NC (US); David Paul HOFF, Raleigh, NC (US); Amey Sudhir KULKARNI, Raleigh, NC (US); Deepti Anup PANT, Austin, TX (US)

(21) Appl. No.: 14/849,811

(22) Filed: Sep. 10, 2015

(51) Int. Cl. G11C 15/04

(52) U.S. Cl. CPC G11C 15/04

(57) ABSTRACT

A method and apparatus for reading bitcell data stored in a content addressable memory (CAM) includes controlling a first compare line of a first column of an array of bitcells to a first logic state while controlling a second compare line of the first column as well as first and second compare lines of each of the other columns of the array to a second logic state during a second mode of operation, in order to provide the bitcell data stored in at least one bitcell of the first column to a respective match line. The method also includes reading the bitcell data on the respective match line.

### FIELD OF DISCLOSURE

Aspects of the present disclosure relate generally to memories, and more particularly, to reading of content addressable memories (CAMs).

### BACKGROUND

Content-addressable memories (CAMs) compare input search data, called “tags” against a table of stored data, and return the address of the matching data. Content-addressable memories (CAMs) may have a single clock cycle throughput making them faster than other hardware-based and software-based search systems. Content-addressable memories (CAMs) can be used in a wide variety of applications requiring high search speeds. These applications include coding and decoding, compression, and image coding. Other applications include classifying and forwarding Internet protocol (IP) packets in network routers.

In networks, like the Internet, a message such an as e-mail or a Web page is transferred by first breaking up the message into small data packets of a few hundred bytes and then sending each data packet individually through the network. The packets are routed from the source, through network routers, and reassembled at the destination to reproduce the original message.

One function of a network router is to compare the destination address of a packet to all possible routes, in order to choose the appropriate route. A content-addressable memory (CAM) is a good choice for implementing this lookup operation due to its fast search capability.

However, the speed of the content-addressable memory (CAM) comes at the cost of increased silicon area on the associated chip as well as at the cost of power consumption. Because portable consumer devices such as cellular phones, tablets, laptops, personal digital assistant (PDA), smart phones, entertainment devices, and the like commonly benefit from smaller form factors and reduced power consumption, techniques to reduce the silicon area occupied by content-addressable memories (CAMs) as well as techniques to reduce their power consumption are desirable.

### SUMMARY

Example implementations of the invention are directed to apparatuses, methods, systems, and non-transitory machine readable media for reading and/or testing a content addressable memory (CAM).

One implementation includes a method for reading a content addressable memory (CAM). The CAM includes a plurality of bitcells arranged into an array of rows and columns, where each column of the array includes both a first compare line and a second compare line coupled to each bitcell included in the column Further, each row of the array includes a match line coupled to each bitcell included in the row, where each match line is configured to indicate a match, during a first mode of operation, between compare data received via the first and second compare lines with bitcell data stored in the bitcells of a respective row. The method include controlling a first compare line of a first column of the array to a first logic state while controlling the second compare line of the first column as well as the first and second compare lines of each of the other columns of the array to a second logic state during a second mode of operation, to provide bitcell data stored in at least one bitcell of the first column to a respective match line. The method also includes reading the bitcell data on the respective match line.

Another implementation includes an apparatus for reading a content addressable memory (CAM). The CAM includes a plurality of bitcells arranged into an array of rows and columns, where each column of the array includes both a first compare line and a second compare line coupled to each bitcell included in the column. Further, each row of the array includes a match line coupled to each bitcell included in the row, where each match line is configured to indicate a match, during a first mode of operation, between compare data received via the first and second compare lines with bitcell data stored in the bitcells of a respective row. The apparatus includes means for controlling a first compare line of a first column of the array to a first logic state while controlling the second compare line of the first column as well as the first and second compare lines of each of the other columns of the array to a second logic state during a second mode of operation, to provide bitcell data stored in at least one bitcell of the first column to a respective match line. The apparatus also includes means for reading the bitcell data on the respective match line.

Another implementation includes an apparatus for reading a content addressable memory (CAM). The CAM includes a plurality of bitcells arranged into an array of rows and columns, where each column of the array includes both a first compare line and a second compare line coupled to each bitcell included in the column. Further, each row of the array includes a match line coupled to each bitcell included in the row, where each match line is configured to indicate a match, during a first mode of operation, between compare data received via the first and second compare lines with bitcell data stored in the bitcells of a respective row. The apparatus includes drive logic coupled to each column of the array, for controlling a first compare line of a first column of the array to a first logic state while controlling the second compare line of the first column as well as the first and second compare lines of each of the other columns of the array to a second logic state during a second mode of operation, to provide bitcell data stored in at least one bitcell of the first column to a respective match line. The apparatus also includes sense logic coupled to the respective match line for reading the bitcell data on the respective match line.

Another implementation a non-transitory computer-readable medium including program code stored thereon for reading a content addressable memory (CAM), the CAM having a plurality of bitcells arranged into an array of rows and columns, where each column of the array includes both a first compare line and a second compare line coupled to each bitcell included in the column Further, each row of the array includes a match line coupled to each bitcell included in the row, and wherein each match line is configured to indicate a match, during a first mode of operation, between compare data received via the first and second compare lines with bitcell data stored in the bitcells of a respective row. The program code includes instructions to control a first compare line of a first column of the array to a first logic state while controlling the second compare line of the first column as well as the first and second compare lines of each of the other columns of the array to a second logic state during a second mode of operation, to provide bitcell data stored in at least one bitcell of the first column to a respective match line. The program code also includes instructions to read the bitcell data on the respective match line.

This Summary is submitted with the understanding that it will not be used to interpret or limit the scope or meaning of the claims. This Summary is not intended to identify key features or essential features of the claimed subject matter, nor is it intended to be used as an aid in determining the scope of the claimed subject matter.

### BRIEF DESCRIPTION OF THE DRAWINGS

The accompanying drawings are presented to aid in the description of implementations of the technology described herein and are provided solely for illustration of the implementations and not limitation thereof.

FIG. 1 is a functional block diagram of an example content-addressable memory (CAM) according to one or more implementations of the technology described herein.

FIG. 2 is a schematic diagram of two example bitcells of a content-addressable memory (CAM) according to one or more implementations of the technology described herein.

FIG. 3 is a schematic diagram of an example sense logic according to one or more implementations of the technology described herein.

FIG. 4 is a logic diagram of an example drive logic according to one or more implementations of the technology described herein.

FIG. 5 is a timing diagram illustrating one or more example signals for reading out bitcell data on a match line according to one or more implementations of the technology described herein.

FIG. 6 is a flowchart illustrating an example process for reading out bitcell data on a match line according to one or more implementations of the technology described herein.

FIG. 7 is an example schematic diagram of a content-addressable memory (CAM) including dedicated read port circuitry for reading bitcell data from bitcells.

The Detailed Description references the accompanying figures. In the figures, the left-most digit(s) of a reference number identifies the figure in which the reference number first appears. The same numbers are used throughout the drawings to reference like features and components.

### DETAILED DESCRIPTION

Commonly, in order to read out the contents of a content-addressable memory (CAM) a dedicated read port is designed into the content-addressable memory (CAM) to facilitate reading and/or testing of the content-addressable memory (CAM). In one aspect, the subject matter disclosed herein is directed to reading and/or testing of the content-addressable memory (CAM) by re-purposing an existing match line in the content addressable memory (CAM) as a bit line and reading out the content addressable memory (CAM) one column at a time. Eliminating the read port saves space because wires that would normally exist coupling the match lines to the read port are eliminated. Eliminating the read port also may improve power consumption because there are fewer wires and components that would dissipate heat.

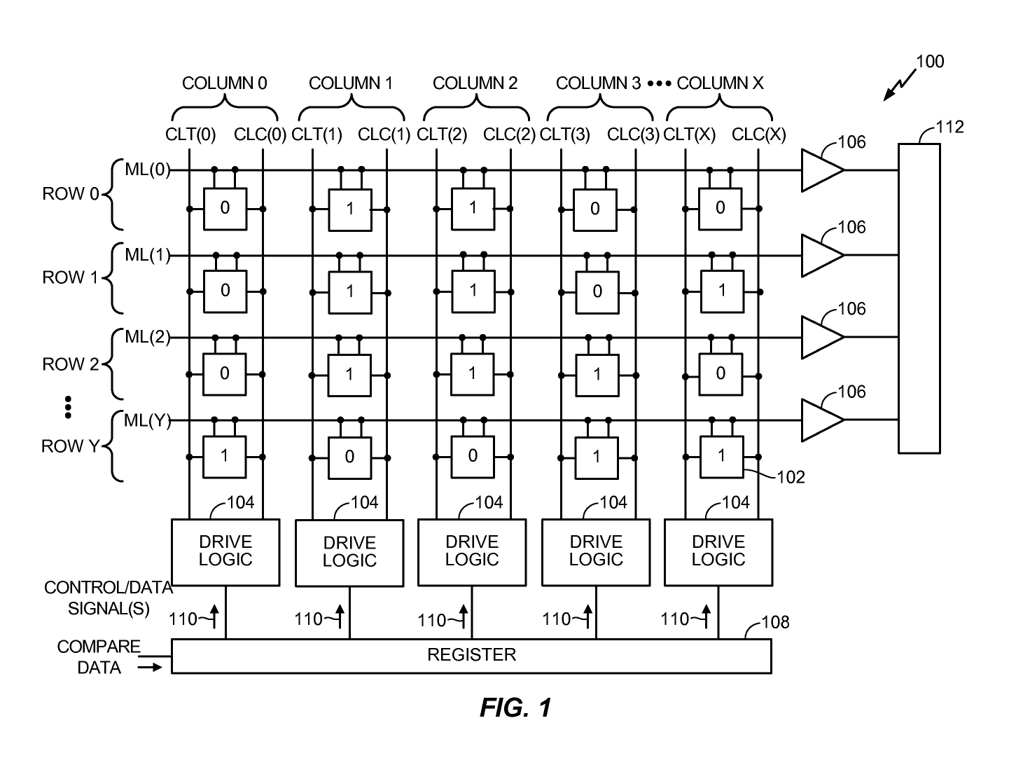

FIG. 1 is a functional block diagram of an example content-addressable memory (CAM) 100 according to one or more implementations of the technology described herein. The illustrated example of CAM 100 includes a two-dimensional (2D) array of bitcells 102 arranged into rows (e.g., ROW 0 through ROW Y) and columns (e.g., COLUMN 0 through COLUMN X). In one example, each bitcell 102 includes both storage and comparison circuitry.

As shown in FIG. 1, each column of the array includes both a first compare line (e.g., compare line true CLT) and a second compare line (e.g., compare line complement CLC) coupled to each bitcell included in a respective column. Further shown in FIG. 1, is that each row of the array includes a match line (e.g., match line ML) coupled to each bitcell included in a respective row. In one example CAM 100 is a binary CAM that supports the storage and searching of binary bits, zero and one. Although FIG. 1 illustrates CAM 100 as including five columns and four rows, in practice CAM 100 may include hundreds, if not more columns and/or rows.

During a compare mode of operation, compare data is received at the drive logic 104 from register 108 and then broadcast from the drive logic 104 to the bitcells 102 via the compare lines (CLT(0)-CLT(X) and CLC(0)-CLC(X)), where the match lines, (ML(0)-ML(Y)), then indicate whether the compare data matches the bitcell data stored in the bitcells of a respective row. Thus, during the compare mode of operation, compare data is broadcast to each bitcell of a respective row, where the match line then indicates whether the compare data matches the row's word. Each match line is also coupled to a respective sense logic 106 for reading out the result of the compare operation.

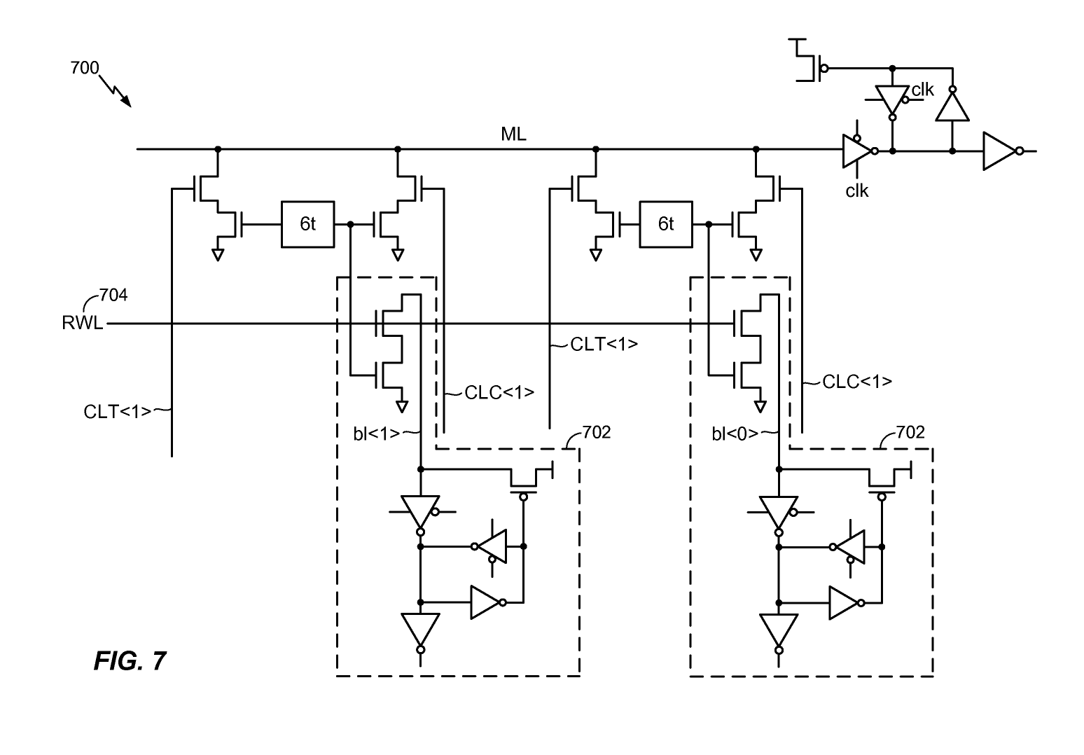

In some situations, there may be a need to provide the capability to actually read out the bitcell data stored in one or more of the bitcells. These situations may include the testing of the CAM, such as to verify the hardware is working correctly or for debugging associated software. However, common solutions for reading out the bitcell data include adding dedicated read ports to the bitcells. For example, FIG. 7 illustrates dedicated read port circuitry 702 with control line 704 added to each bitcell for reading out the bitcell data of illustrative CAM 700. Adding dedicated read port circuitry adds area, complexity, and increases power consumption of the circuit for these testing operations. Accordingly, as will be described in more detail below, embodiments of the present disclosure include improved drive logic 104, register 108, and optional reassembly logic 112 that allows the re-purposing of the existing match lines ML(0)-ML(Y) to serve as bit lines for reading out bitcell data without the need for dedicated read port circuitry.

As shown in FIG. 1, each drive logic 104 is coupled to receive one or more control/data signals 110 from register 108. Register 108 is configured to generate the control/data signals 110 to control the drive logic 104, such that the CAM 100 operates in one of two modes of operation. In a first mode of operation, such as the compare mode described above, the register 108 generates the control/data signals 110 such that the drive logic 104 operates the compare lines CLT(0)-CLT(X) and CLC(0)-CLC(X) to allow CAM 100 to compare bitcell data pairs stored at the bitcells 102 with the compare data received at drive logic 104, where the match lines ML(0)-ML(Y), then indicate whether the compare data pair matches the bitcell data pair stored in the bitcells of a respective row. In a second mode of operation, such as a read mode, the register 108 generates the control/data signals 110 such that the drive logic 104 operates the compare lines CLT(0)-CLT(X) and CLC(0)-CLC(X) to allow one or more match lines ML(0)-ML(Y) to serve as bit lines for reading out the bitcell data. These and other aspects will be described in more detail below.

In one embodiment, CAM 100 is a subsystem included within a larger electronic system. The electronic system may be a mobile phone, a computer, a digital camera, a medical device, or otherwise, and may further include a computing or processing unit for system level operation or other functionality of the electronic system. For example, the electronic system may be a mobile phone that also includes a central processor unit and radio frequency or microwave electronics for wireless communications.

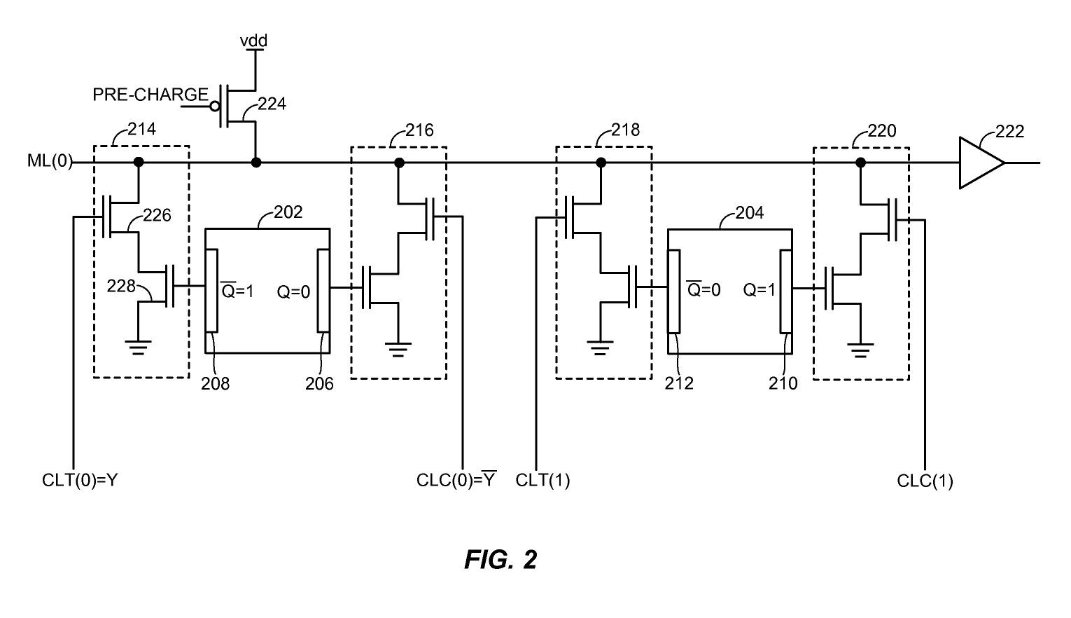

FIG. 2 is a schematic diagram of two example bitcells of a content-addressable memory (CAM) according to one or more implementations of the technology described herein. A first bitcell of FIG. 2 includes bitcell storage 202 and associated bitcell compare circuitry (shown as compare ports 214 and 216). A second bitcell of FIG. 2 includes bitcell storage 204 and associated bitcell compare circuitry (shown as compare ports 218 and 220). The two bitcells of FIG. 2 are possible implementations of two bitcells included in two separate columns of ROW 0 of CAM 100 in FIG. 1.

As further shown in FIG. 2, the bitcell storage 202 includes a first compare data output 206 for providing true bitcell data (e.g., Q) stored in the bitcell and a second compare data output 208 for providing complementary bitcell data (e.g., Q̅). Similarly, the bitcell storage 204 includes a first compare data output 210 for providing true bitcell data (e.g., Q) stored in the bitcell and a second compare data output 212 for providing complementary bitcell data (e.g., Q̅). In the illustrated example of FIG. 2, bitcell storage 202 stores bitcell data equivalent to a logic LOW (or logic “0”) and thus provides a logic LOW via first compare data output 206 and a logic HIGH (or logic “1”) via second compare data output 208. Similarly, bitcell storage 204 is shown as storing bitcell data equivalent to a logic HIGH and thus provides a logic HIGH via first compare data output 210 and a logic LOW via the second compare data output 212.

FIG. 2 also illustrates a pre-charge logic 224 coupled to match line ML(0) and a sense logic 222 for reading out one or more values presented on the match line ML(0).

During a compare mode of operation, pre-charge logic 224 pre-charges the match line ML(0) to a logic HIGH state, putting it temporarily in a state indicating a match. Drive logic (e.g., drive logic 104 of FIG. 1) then broadcasts true compare data to compare lines CLT(0) and CLT(1), as well as complementary compare data to compare lines CLC(0) and CLC(1). Compare port 216 then compares the bitcell data on first compare data output 206 with the compare data on compare line CLC(0), while compare port 214 compares the bitcell data on the second compare data output 208 with the compare data on compare line CLT(0). That is, the true bitcell data provided at compare data output 206 is compared with the complementary compare data received via compare line CLC(0), while complementary bitcell data provided at compare data output 208 is compared with true compare data received via compare line CLT(0).

Similarly, compare port 220 compares the true bitcell data on first compare data output 210 with the complementary compare data on compare line CLC(1), while compare port 218 compares the complementary bitcell data on the second compare data output 212 with the true compare data on compare line CLT(1).

In one aspect, the true bitcell data at one compare port (e.g., compare port 206) and the complementary bitcell data at a corresponding compare port (e.g., compare port 208) of the same bitcell storage (e.g., 202) may be referred to as a bitcell data pair (e.g., (1,0) or (0,1)). Similarly, the true compare data provided by one compare line (e.g., CLT(0)) and the complementary compare data provided by a corresponding compare line (e.g., CLC(0)) of the same column may be referred to as a compare data pair (e.g., (1,0) or (0,1)). In one embodiment a mismatch refers to the true bitcell data of one bitcell data pair not matching the true compare data of a corresponding compare data pair and/or the complementary bitcell data not matching the corresponding complementary compare data.

However, as mentioned above, each of the compare ports 214 and 218 are coupled to compare the complementary bitcell data with the true compare data and each of the compare ports 216 and 220 are coupled to compare the true bitcell data with the complementary compare data. Thus, compare port 214 (and 218) is configured to control the transistors 226 and 228 within the compare port 214 to allow the match line ML(0) to remain in the logic HIGH state indicating a match if the complementary bitcell data at the compare data output 208 is not the same as true compare data received via the compare line CLT(0). For example, if the complementary bit cell data provided at compare data output 208 is a logic HIGH (e.g., Q̅=1) and the true compare data provided via compare line CLT(0) is a logic LOW (e.g., Y=0) then there is a match between the data pairs. That is, it follows that if Q̅≠Y, then Q=Y. Similarly, for compare port 216, if Q≠Y̅, then Q≠Y.

In the case of a mismatch between data pairs, the compare port 214 controls the transistors 226 and 228 to effectively pull the match line ML(0) to a logic LOW state (e.g., ground) indicating the mismatch. A mismatch may be indicated if the complementary bit cell data at the compare data output 208 is the same as the true compare data. That is, it follows that if Q̅=Y, then Q≠Y. Similarly, for compare port 216, if Q=Y̅, then Q≠Y.

In one embodiment, the transistors (e.g., 226 and 228) within each compare port 214, 216, 218, and 220 are n-channel field-effect transistors (nFET). Thus, in one example a compare port may indicate a mismatch by pulling the match line ML(0) to the logic LOW state only if both the bitcell data and the compare data received at the compare port are a logic HIGH (e.g., “1”).

A mismatch between any of the bitcell data pairs stored in this row and the compare data pairs provided will cause the match line ML(0) to transition to the logic LOW state, thus indicating a mismatch. If, however, the compare data pairs broadcast on each compare line matches with their respective stored bitcell data pairs, then match line ML(0) will remain in its pre-charged logic HIGH state indicating a match. Thus, during the compare mode of operation, the state of the match line, after the comparison operation is then read out by sense logic 222 via match line ML(0).

In addition to the compare mode of operation, discussed above, embodiments disclosed herein include a second (e.g., read) mode of operation for reading out the bitcell data stored in the bitcells. As further discussed above, this is achieved without the addition of dedicated read port circuitry and instead includes the reading out of bitcell data via the existing match lines (e.g., ML(0)).

In one aspect, reading out bitcell data stored in a CAM includes controlling a first compare line of a first column of the array to a first logic state while controlling the second compare line of the first column, as well as the first and second compare lines of each of the other columns of the array, to a second logic state during the read mode of operation. Thus, during a read operation of the first column of the array, the first compare line of the first column is the only compare line of the array that is enabled (i.e., each of the other compare lines included in the array are disabled). Doing so, allows the match lines to serve as a bit line for allowing the bitcell data to then be read out via existing sense logic.

By way of example, attention is again directed to FIG. 2, where the CAM 100 is now in the read mode of operation. During the read mode of operation, pre-charge logic 224 pre-charges the match line ML(0) to a logic HIGH state. Drive logic (e.g., drive logic 104 of FIG. 1) then controls compare line CLT(0) to a first logic state (e.g., Y=1), while controlling the compare lines CLC(0), CLT(1), and CLC(1) to a second logic state (e.g., Y̅=0) in order to read out the bitcell data stored in bitcell storage 202. With a logic HIGH on compare line CLT(0) and a logic HIGH on compare data output 208, compare port 214 then pulls match line ML(0) to the logic LOW state, effectively transferring the bitcell data (e.g., “0”) of bitcell storage 202 to the match line ML(0). In one aspect, controlling compare line CLT(0) to a logic HIGH state, while controlling the compare lines CLC(0), CLT(0), and CLC(1) of the other columns in the array to the logic LOW state allows for a column-wise read out of stored bitcell data. For example, referring back to FIG. 1, a read operation of column 0 may allow the simultaneous readout of each bitcell in column 0 via their respective match lines (ML(0)-ML(Y)).

Returning now back to FIG. 2, a read operation of a second column may then be performed by again pre-charging the match line ML(0) to a logic HIGH state and then controlling compare line CLT(1) to a logic HIGH state, while controlling the compare lines CLT(0), CLC(0) and CLC(1) to a logic LOW state in order to read out the bitcell data stored in bitcell storage 204. With a logic HIGH on compare line CLT(1) and a logic LOW on compare data output 212, compare port 218 allows match line ML(0) to remain in the logic HIGH state, effectively transferring the bitcell data (e.g., “1”) of bitcell storage 204 to the match line ML(0). After the completion of a read operation of one or more columns, the data read out on the match lines may then be reassembled into rows by way of reassembly logic 112, shown in FIG. 1. Reassembly logic 112 may be a digital sequencer or may be a processor and memory that includes a reassembly routine for reassembling the data read out on the match lines back into rows. In one implementation, reassembly may be accomplished using external hardware and/or software.

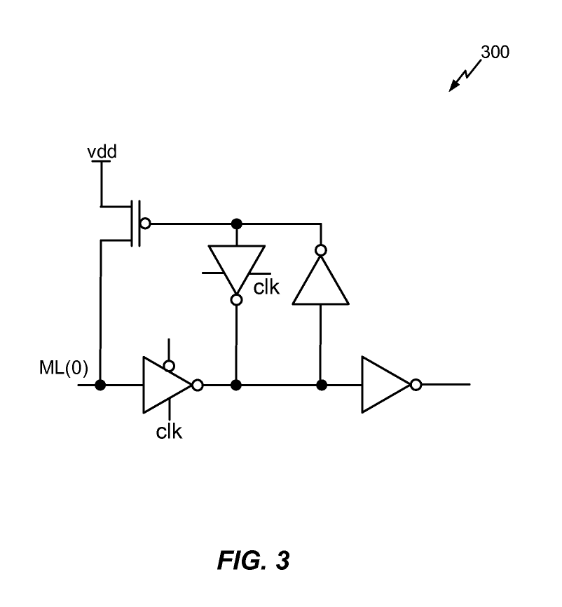

FIG. 3 is a schematic diagram of an example sense logic 300 according to one or more implementations of the technology described herein. Sense logic 300 is one possible implementation for sense logic 222 illustrated in FIG. 2, and for each sense logic 106 illustrated in FIG. 1. Thus, the same sense logic 300 may be configured to read out compare results (i.e., match or mismatch) during the compare mode of operation and to read out stored bitcell data during the read mode of operation, both via an associated match line.

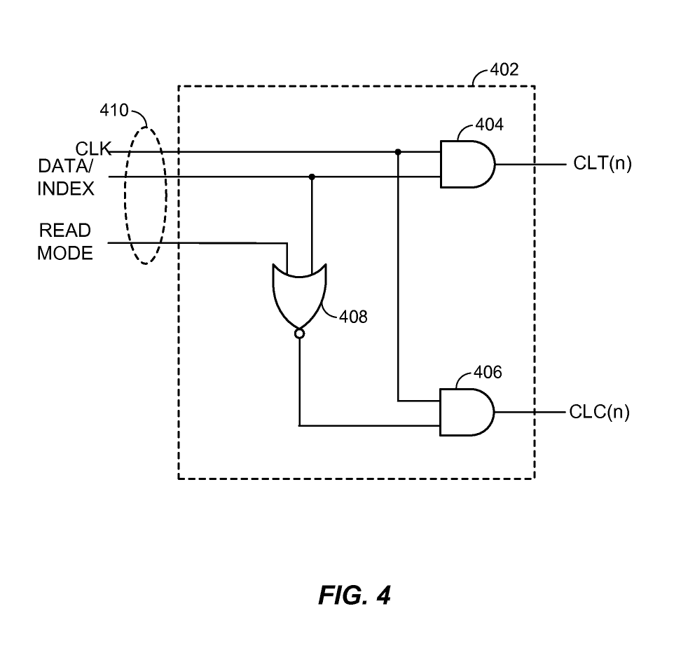

FIG. 4 is a logic diagram of an example drive logic 402 according to one or more implementations of the technology described herein. Drive logic 402 is one possible implementation of each drive logic 104 illustrated in FIG. 1. The illustrated example of drive logic 402 includes a first logic gate 404, shown as an AND gate, a second logic gate 406, shown as an AND gate, and a third logic gate 408, shown as a NOR gate.

As shown in FIG. 4, drive logic 402 is coupled to receive one or more control/data signals 410 from a register, such as register 108 of FIG. 1. Thus, in one example, control/data signals 410 are one possible implementation of the control/data signals 110 shown in FIG. 1. As shown in FIG. 4, control/data signals 410 may include a clock signal (CLK), a DATA/INDEX signal, and a READ MODE signal. In one embodiment, the DATA/INDEX signal is a multi-function signal that provides the compare data that is to be provided to the compare lines during the compare mode of operation, but then provides an indication of whether the respective column is selected for the read operation during the second mode of operation. The READ MODE signal provides an indication of whether the CAM 100 is in the read mode of operation. In the illustrated example, a logic LOW on the READ MODE signal indicates the compare mode of operation, while a logic HIGH indicates the read mode of operation.

FIG. 4 further illustrates that an output of first logic gate 404 is coupled to control the logic state of a first compare line CLT(n) of respective column, while the second logic gate 406 is coupled to control the logic state of a second compare line CLC(n) of the same column During the read mode of operation, the DATA/INDEX signal controls logic gate 404 to select the respective column of the first compare line CLT(n) for a read operation, while the third logic gate 408 is coupled to disable the second logic gate 406 during the read mode of operation in response to the READ MODE signal being in the logic HIGH state to disable the second compare line CLC(n). Also, as shown in FIG. 4, if, during a read mode of operation, a column is not selected for a read operation, the first logic gate 404 disables (e.g., holds to a logic LOW) the first compare line CLT(n) in response to the DATA/INDEX signal being a logic LOW, while logic gate 408 controls logic gate 406 to disable the second compare line CLC(n) in response to the READ MODE signal being a logic HIGH.

During the compare mode of operation, the compare data is provided by way of the DATA/INDEX signal, where logic gate 404 provides the true compare data to first compare line CLT(n) and where logic gate 408 controls logic gate 406 to provide the complementary compare data to compare line CLC(n).

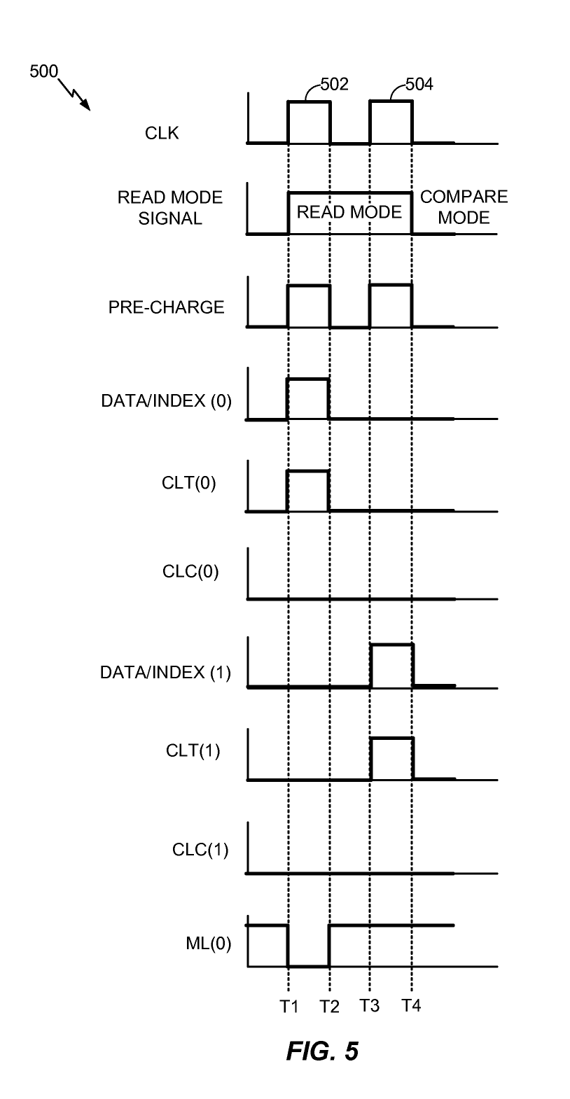

The operation of drive logic 402 in conjunction with the bitcells of FIG. 2, will now be described with reference to the timing diagram 500 of FIG. 5. At time T1, the clock signal CLK transitions to a logic HIGH state indicating the beginning of a clock cycle 502. Also, at time T1, the READ MODE signal transitions to a logic HIGH state, indicating the read mode of operation. Also, at time T1, the match line ML(0) has been precharged to the logic HIGH state by way of pre-charge logic 224. Further, at time T1, the drive logic 402 associated with column 0 receives a DATA/INDEX signal that transitions to a logic HIGH state, indicating that column 0 is selected for a read operation. Thus, the respective drive logic 402 for column 0, controls the compare line CLT(0) to a logic HIGH state and the compare line CLC(0) to a logic LOW state.

Similarly, at time T1, the respective drive logic 402 associated with column 1 receives a DATA/INDEX signal that is a logic LOW state, indicating that column 1 is not selected for a read operation. Thus, the drive logic 402 for column 1, controls both the compare line CLT(1) and the compare line CLC(1) to the logic LOW state. With CLT(0) at the logic HIGH state and CLC(0), CLT(1), and CLC(1) at the logic LOW state, bitcell data stored in bitcell storage 202 is provided onto match line ML(0), as shown in FIG. 5, by the transitioning of match line ML(0) to the logic low state at time T1.

Next, a read operation of column 1 is commenced at time T3 coinciding with the beginning of another clock cycle 504. At time T3, the READ MODE signal remains in the logic HIGH state, still indicating the read mode of operation. Also, between time T2 and time T3, pre-charge logic 224, again, precharges the match line ML(0) to the logic HIGH state such that the match line ML(0) is precharged by time T3. Further, at time T3, the drive logic 402 associated with column 0 receives a DATA/INDEX signal that transitions to a logic LOW state, indicating that column 0 is not selected for a read operation. Thus, the drive logic 402 for column 0, controls the both the compare line CLT(0) and the compare line CLC(0) to a logic LOW state.

Similarly, at time T3, the drive logic 402 associated with column 1 receives a DATA/INDEX signal that is a logic HIGH state, indicating that column 1 is now selected for a read operation. Thus, the drive logic 402 for column 1, controls the compare line CLT(1) to the logic HIGH state and the compare line CLC(1) to the logic LOW state. With CLT(1) at the logic HIGH state and CLC(1), CLT(0), and CLC(0) at the logic LOW state, bitcell data stored in bitcell storage 204 is provided onto match line ML(0), as shown in FIG. 5, by allowing the match line ML(0) to remain in the logic HIGH state at time T3. Upon completion of one or more read operations of one or more columns, READ MODE signal may transition back to the logic LOW state, such as shown at time T4, thus indicating an end of the read mode and the return to the compare mode of operation.

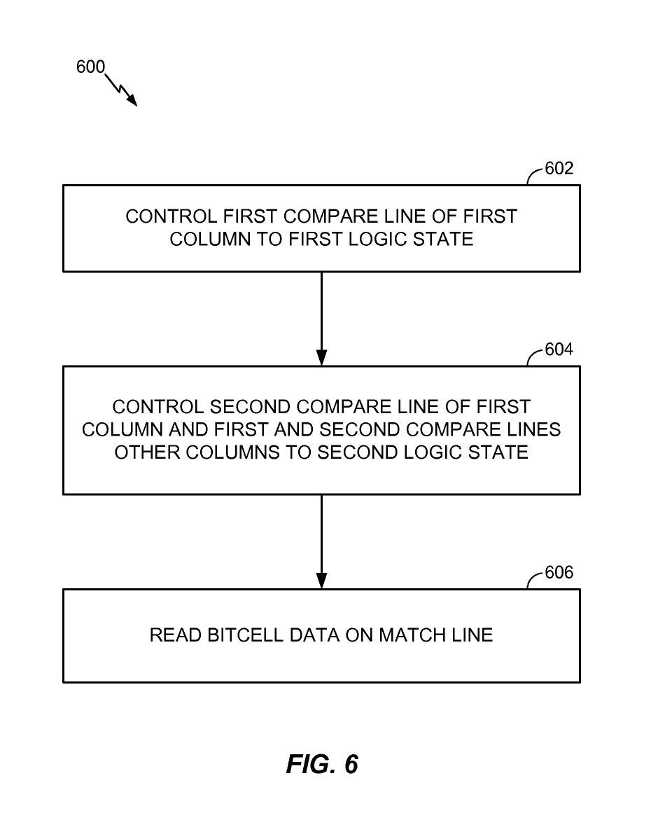

FIG. 6 is a flowchart illustrating an example process 600 for reading out bitcell data on a match line according to one or more implementations of the technology described herein. In process block 602, a drive logic, such as drive logic 104 or drive logic 402, controls a first compare line of a first column of a CAM array to a first logic state (e.g., HIGH). In process block 604, the drive logic controls the second compare line as well as the first and second compare lines of each of the other columns included in the array to a second (e.g., LOW) logic state. As mentioned above, controlling the first compare line of a first column to the first logic state, while controlling the second compare line of the first column and the first and second compare lines of the other columns allows the bitcell data stored in the bitcells of the first column to be provided to their respective match lines. In process block 606 the bitcell data is read via respective match lines, by, for example, sense logic 106, sense logic 222, or sense logic 300.

Aspects of the technology described herein and related drawings are directed to specific implementations of the technology. Alternative implementations may be devised without departing from the scope of the technology described herein. Additionally, well-known elements of the technology will not be described in detail or will be omitted so as not to obscure the relevant details.

Although steps and decisions of various methods may have been described serially in this disclosure, some of these steps and decisions may be performed by separate elements in conjunction or in parallel, asynchronously or synchronously, in a pipelined manner, or otherwise. There is no particular requirement that the steps and decisions be performed in the same order in which this description lists them, except where explicitly so indicated, otherwise made clear from the context, or inherently required. It should be noted, however, that in selected variants the steps and decisions are performed in the order described above. Furthermore, not every illustrated step and decision may be required in every implementation/variant in accordance with the technology described herein, while some steps and decisions that have not been specifically illustrated may be desirable or necessary in some implementation/variants in accordance with the technology described herein.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Those of skill would further appreciate that the various illustrative logical blocks, modules, circuits, and algorithm steps described in connection with the implementations disclosed herein may be implemented as electronic hardware or a combination of hardware and software. To show clearly this interchangeability of hardware and hardware and software combinations, various illustrative components, blocks, modules, circuits, and steps have been described above generally in terms of their functionality. Whether such functionality is implemented as hardware or combination of hardware and software depends upon the particular application and design constraints imposed on the overall system. Skilled artisans may implement the described functionality in varying ways for each particular application, but such implementation decisions should not be interpreted as causing a departure from the scope of the present technology described herein.

The various illustrative logical blocks, modules, and circuits described in connection with the implementation disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

A method or algorithm described in connection with the aspects disclosed herein may be implemented directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in an access terminal. Alternatively, the processor and the storage medium may reside as discrete components in an access terminal.

The previous description of the disclosed implementations is provided to enable any person skilled in the art to make or use the technology described herein. Various modifications to these implementations will be readily apparent to those skilled in the art, and the generic principles defined herein may be applied to other implementations without departing from the spirit or scope of the technology described herein. Thus, aspects of the technology described herein are not intended to be limited to the implementations shown herein, but is to be accorded the widest scope consistent with the principles and novel features disclosed herein.

1. A method for reading bitcell data stored in a content addressable memory (CAM), the CAM having a plurality of bitcells arranged into an array of rows and columns, wherein each column of the array includes both a first compare line and a second compare line coupled to each bitcell included in the column, wherein each row of the array includes a match line coupled to each bitcell included in the row, and wherein each match line is configured to indicate a match, during a first mode of operation, between compare data pairs received via the first and second compare lines with bitcell data pairs stored in the bitcells of a respective row, the method comprising:
receiving, at drive logic associated with each of the columns, one or more control/data signals, wherein the one or more control/data signals:
includes at least one compare data of the compare data pairs during the first mode of operation,
indicates whether the CAM is in the first or the second mode of operation, and
indicates whether a respective column is selected for a read operation during a second mode of operation;
in response to the one or more control/data signals indicating that the CAM is in the second mode of operation and that the first column is selected for the read operation, controlling the first compare line of a first column of the array to a first logic state while controlling the second compare line of the first column and the first and second compare lines of each of the other columns of the array to a second logic state during the second mode of operation, to provide the bitcell data stored in at least one bitcell of the first column to a respective match line; and
reading the bitcell data on the respective match line.

2. The method of claim 1, wherein controlling the first compare line of the first column of the array to the first logic state while controlling the second compare line of the first column and the first and second compare lines of each of the other columns of the array to the second logic state during the second mode of operation, includes providing the bitcell data stored in each bitcell of the first column to respective match lines of the bitcells of the first column, the method further comprising reading the bitcell data on each respective match line.

3. The method of claim 2, further comprising:
in response to the one or more control/data signals indicating that the CAM is in the second mode of operation and that a second column is selected for the read operation, controlling the first compare line of the second column of the array to the first logic state while controlling the second compare line of the second column and the first and second compare lines of each of the other columns of the array to the second logic state during the second mode of operation, to provide the bitcell data stored in each bitcell of the second column to respective match lines of the bitcells of the second column; and
reading the bitcell data on each respective match line.

4. The method of claim 3, further comprising reassembling the bitcell data read on the match lines into rows.

5. The method of claim 1, further comprising pre-charging the match lines during the second mode of operation.

6. The method of claim 1, wherein the first mode of operation is a compare mode for comparing the compare data pair received via the first and second compare lines with the bitcell data pairs stored in the bitcells, and wherein the second mode of operation is a read mode for reading out the bitcell data stored in the bitcells to the match lines.

7. The method of claim 1, wherein the first logic state is a logic HIGH and the second logic state is a logic LOW.

8. An apparatus for reading a content addressable memory (CAM), the CAM having a plurality of bitcells arranged into an array of rows and columns, wherein each column of the array includes both a first compare line and a second compare line coupled to each bitcell included in the column, wherein each row of the array includes a match line coupled to each bitcell included in the row, and wherein each match line is configured to indicate a match, during a first mode of operation, between compare data pairs received via the first and second compare lines with bitcell data pairs stored in the bitcells of a respective row, the apparatus comprising:
means for receiving one or more control/data signals, wherein the one or more control/data signals:
includes at least one compare data of the compare data pairs for a respective column during the first mode of operation,
indicates whether the CAM is in the first or the second mode of operation, and
indicates whether the respective column is selected for a read operation during a second mode of operation;
means for controlling, in response to the one or more control/data signals indicating that the CAM is in the second mode of operation and that the first column is selected for the read operation, the first compare line of a first column of the array to a first logic state while controlling the second compare line of the first column and the first and second compare lines of each of the other columns of the array to a second logic state during the second mode of operation, to provide bitcell data stored in at least one bitcell of the first column to a respective match line; and
means for reading the bitcell data on the respective match line.

9. The apparatus of claim 8, wherein the means for controlling the first compare line of the first column of the array to the first logic state while controlling the second compare line of the first column and the first and second compare lines of the other columns of the array to the second logic state during the second mode of operation, includes means for providing the bitcell data stored in each bitcell of the first column to respective match lines of the bitcells of the first column, the apparatus further comprising means for reading the bitcell data on each respective match line.

10. The apparatus of claim 9, further comprising:
means for, in response to the one or more control/data signals indicating that the CAM is in the second mode of operation and that a second column is selected for the read operation, controlling a first compare line of the second column of the array to the first logic state while controlling the second compare line of the second column and the first and second compare lines of each of the other columns of the array to the second logic state during the second mode of operation, to provide the bitcell data stored in each bitcell of the second column to respective match lines of the bitcells of the second column; and
means for reading the bitcell data on each respective match line.

11. The apparatus of claim 10, further comprising means for reassembling the bitcell data read on the match lines into rows.

12. The apparatus of claim 9, further comprising means for pre-charging the match lines during the second mode of operation.

13. The apparatus of claim 9, wherein the first mode of operation is a compare mode for comparing the compare data pair received via the first and second compare lines with the bitcell data pair stored in the bitcells, and wherein the second mode of operation is a read mode for reading out the bitcell data stored in the bitcells to the match lines.

14. The apparatus of claim 9, wherein the first logic state is a logic HIGH and the second logic state is a logic LOW.

15. An apparatus for reading a content addressable memory (CAM), the CAM having a plurality of bitcells arranged into an array of rows and columns, wherein each column of the array includes both a first compare line and a second compare line coupled to each bitcell included in the column, wherein each row of the array includes a match line coupled to each bitcell included in the row, and wherein each match line is configured to indicate a match, during a first mode of operation, between compare data pairs received via the first and second compare lines with bitcell data pairs stored in the bitcells of a respective row, the apparatus comprising:
drive logic coupled to each column of the array, the drive logic configured to receive one or more control/data signals, wherein the one or more control/data signals:
includes at least one compare data of the compare data pairs during the first mode of operation,
indicates whether the CAM is in the first or the second mode of operation, and
indicates whether a respective column is selected for a read operation during the second mode of operation, wherein drive logic is further configured to, in response to the one or more control/data signals indicating that the CAM is in the second mode of operation and that the first column is selected for the read operation, control the first compare line of a first column of the array to a first logic state while controlling the second compare line of the first column and the first and second compare lines of each of the other columns of the array to a second logic state during the second mode of operation, to provide bitcell data stored in at least one bitcell of the first column to a respective match line; and
sense logic coupled to the respective match line to read the bitcell data on the respective match line.

16. The apparatus of claim 15, wherein the drive logic is configured to control the first compare line of the first column to provide the bitcell data stored in each bitcell of the first column to respective match lines of the bitcells of the first column, the apparatus further comprising sense logic coupled to each respective match line for reading the bitcell data on each respective match line.

17. The apparatus of claim 16, wherein the drive logic is configured to, in response to the one or more control/data signals indicating that the CAM is in the second mode of operation and that a second column is selected for the read operation, control a first compare line of the second column of the array to the first logic state while controlling the second compare line of the second column and the first and second compare lines of each of the other columns of the array to the second logic state during the second mode of operation, to provide the bitcell data stored in each bitcell of the second column to respective match lines of the bitcells of the second column, and wherein the sense logic is configured to read the bitcell data on each respective match line.

18. The apparatus of claim 17, further comprising reassembly logic configured to reassemble the bitcell data read on the match lines into rows.

19. The apparatus of claim 15, further comprising pre-charge logic configured to pre-charge the match lines during the second mode of operation.

20. The apparatus of claim 15, wherein the first mode of operation is a compare mode for comparing the compare data pairs received via the first and second compare lines with bitcell data pairs stored in the bitcells, and wherein the second mode of operation is a read mode for reading out the bitcell data stored in the bitcells to the match lines.

21. The apparatus of claim 15, wherein the first logic state is a logic HIGH and the second logic state is a logic LOW.

22. The apparatus of claim 15, wherein the drive logic comprises:
a first logic gate coupled to control a logic state of the first compare line of the first column;
a second logic gate coupled to control a logic state of the second compare line of the first column;
a third logic gate coupled to disable the second logic gate during the second mode of operation, such that the second compare line is controlled to the second logic state, if the first column is not selected for a read operation.

23. The apparatus of claim 22, wherein,
the first logic gate is an AND gate to be coupled to receive a clock signal and a DATA/INDEX signal,
the third logic gate is a NOR gate to be coupled to receive the DATA/INDEX signal and a READ MODE signal, and
the second logic gate is an AND gate to be coupled to receive the clock signal and an output of the NOR gate.

24. The apparatus of claim 23, wherein the DATA/INDEX signal includes compare data during the first mode of operation, and indicates whether the first column is selected for the read operation during the second mode of operation.

25. A non-transitory computer-readable medium including a program code stored thereon for reading a content addressable memory (CAM), the CAM having a plurality of bitcells arranged into an array of rows and columns, wherein each column of the array includes both a first compare line and a second compare line coupled to each bitcell included in the column, wherein each row of the array includes a match line coupled to each bitcell included in the row, and wherein each match line is configured to indicate a match, during a first mode of operation, between compare data pairs received via the first and second compare lines with bitcell data pairs stored in the bitcells of a respective row, the program code comprising instructions to:
receive, at drive logic associated with each of the columns, one or more control/data signals, wherein the one or more control/data signals:
includes at least one compare data of the compare data pairs during the first mode of operation,
indicates whether the CAM is in the first or the second mode of operation, and
indicates whether a respective column is selected for a read operation during a second mode of operation;
control, via execution of the instructions included in the program code of the non-transitory computer-readable medium, and in response to the one or more control/data signals indicating that the CAM is in the second mode of operation and that the first column is selected for the read operation, the first compare line of a first column of the array to a first logic state while controlling the second compare line of the first column and the first and second compare lines of each of the other columns of the array to a second logic state during the second mode of operation, to provide bitcell data stored in at least one bitcell of the first column to a respective match line; and
read, via execution of the instructions included in the program code of the non-transitory computer-readable medium, the bitcell data on the respective match line.

26. The non-transitory computer-readable medium of claim 25, further comprising instructions to:
control, in response to the one or more control/data signals indicating that the CAM is in the second mode of operation and that a second column is selected for the read operation, the first compare line of the second column of the array to the first logic state while controlling the second compare line of the second column and the first and second compare lines of each of the other columns of the array to the second logic state during the second mode of operation, to provide the bitcell data stored in each bitcell of the second column to respective match lines of the bitcells of the first column; and
read the bitcell data on each respective match line.

27. The non-transitory computer-readable medium of claim 26, further comprising instructions to reassemble the bitcell data read on the match lines into rows.

28. The non-transitory computer-readable medium of claim 25, further comprising instructions to pre-charge the match lines during the second mode of operation.

29. The non-transitory computer-readable medium of claim 25, wherein the first mode of operation is a compare mode for comparing the compare data pairs received via the first and second compare lines with bitcell data pairs stored in the bitcells, and wherein the second mode of operation is a read mode for reading out the bitcell data stored in the bitcells to the match lines.

30. The non-transitory computer-readable medium of claim 25, wherein the first logic state is a logic HIGH and the second logic state is a logic LOW.
